(19) United States
(12) Patent Application Publication
(10) Pub. No.: US 2009/0004820 A1
(43) Pub. Date: Jan. 1, 2009

(54) Method of Forming Isolation Layer in Flash Memory Device

(75) Inventors: Dong Hwan Lee, Gangbuk-gu (KR); Byung Soo Park, Icheon-Si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-Si (KR)

(21) Appl. No.: 12/019,959

(22) Filed: Jan. 25, 2008

(30) Foreign Application Priority Data
Jun. 27, 2007 (KR) 10-2007-063590

(51) Int. Cl. H01L 21/76

(52) U.S. Cl. 438/441; 257/E21.54

(57) ABSTRACT

The invention relates to a method of forming an isolation layer in a flash memory device and comprises providing a semiconductor substrate in which a tunnel insulating layer and a conductive layer are formed on an active region and a trench is formed on an isolation region; forming a first insulating layer in a lower portion of the trench; forming a second insulating layer on the semiconductor substrate and the first insulating layer including the trench to protect a side wall of the conductive layer; forming a third insulating layer in the trench to form an isolation layer; and adjusting an effective field height (EFH) of the isolation layer through a first etching process.

### CROSS-REFERENCE TO RELATED APPLICATION

Priority to Korean Patent Application No. 2007-63590, filed on Jun. 27, 2007, the disclosure of which is incorporated herein by reference in its entirety, is claimed.

### BACKGROUND OF THE INVENTION

The invention relates to a method of forming an isolation layer in a flash memory device, more particularly to a method that can prevent a side wall of a floating gate from being damaged, thereby reducing an interference phenomenon.

In the process for filling a trench with a high density plasma (HDP) oxide layer, a side wall of a conductive layer used for a floating gate is damaged by plasma so that a flat side wall of the conductive layer becomes coarse and numerous protrusions are formed on the side wall of the conductive layer. As a result, a profile of the conductive layer is transformed.

In addition, due to the transformation of the conductive layer profile, a contact surface between the conductive layer and a dielectric layer is reduced, and so a coupling ratio (CR) is decreased. Ultimately, a decrease in the coupling ratio also decreases the operating speed of a cell.

If an isolation layer is formed through a conventional process, an effective field height (EFH) of the isolation layer is not adjusted to a desirable value, thus generating an interference phenomenon between adjacent cells. In particular, as the device becomes miniaturized, the above interference phenomenon problem becomes more significant.

Further, if the isolation layer is formed through a conventional process, which includes performing a process for forming a mask and an etching process, the process becomes complicated and the side wall of the conductive layer used for the floating gate is damaged by the plasma during a dry etching process so that a profile of the conductive layer is transformed. As a result, in a program operation and an erase operation, the threshold voltage distribution of the cell is expanded, and this may cause the program operation and the erase operation in the cell to fail.

### SUMMARY OF THE INVENTION

In the invention, a protective layer is formed on a side wall of a conductive layer before performing a process for forming a high density plasma (HDP) oxide layer. Thus, it is possible to prevent a side wall of the conductive layer from being damaged by the plasma during the process for forming the high density plasma (HDP) oxide layer. Accordingly, the invention can prevent a flat surface of the side wall of the conductive layer from becoming coarse by inhibiting the formation of numerous protrusions which may be formed on a coarse surface.

In addition, in the invention, after an isolation layer comprising a plurality of insulating layers formed sequentially in order of increasing etching selectivity ratio is formed in the trench, some of the isolation layer remains on a side wall of the conductive layer during an etching process performed to adjust the effective field height of the isolation layer. Accordingly, the invention can lower the effective field height of the isolation layer to a desired value.

A method of forming an isolation layer in a flash memory device according to one embodiment of the invention comprises: providing a semiconductor substrate comprising a tunnel insulating layer and a conductive layer formed on an active region of the substrate and a trench formed on an isolation region of the substrate; forming a first insulating layer in a lower portion of the trench; forming a second insulating layer on the semiconductor substrate and the first insulating layer including the trench to protect a side wall of the conductive layer; forming a third insulating layer in the trench to form an isolation layer; and performing a first etching process to adjust an effective field height (EFH) of the isolation layer.

Here, the first insulating layer preferably is formed of polysilazane (PSZ) layer formed in a spin-coating manner. The method of one embodiment of the invention preferably further comprises performing a heat treatment process after the PSZ layer is formed. Preferably, the second insulating layer is formed from a material whose etching selectivity ratio differs from that of the third insulating layer, with the second insulating layer being formed from nitride. Preferably, the second insulating layer is formed through a low pressure-chemical vapor deposition (LP-CVD) method.

The third insulating layer preferably comprises a high density plasma (HDP) oxide layer. Also, the process for forming the third insulating layer and a second etching process for removing an overhang formed on an edge portion of an upper portion of the trench are preferably repeatedly performed. The second etching process is preferably a wet etching process, and the second insulating layer formed on a side wall of the conductive layer preferably is removed in the first etching process.

A method of forming an isolation layer in a flash memory device according to another embodiment of the invention comprises: providing a semiconductor substrate comprising a tunnel insulating layer and a conductive layer formed on an active region of the substrate and a trench formed on an isolation region of the substrate; forming a first insulating layer on a bottom surface of the trench; forming a second insulating layer on the semiconductor substrate and the first insulating layer including the trench, the second insulating layer comprising a plurality of layers formed in order of increasing etching selectivity ratio; planarizing the second insulating layer to form an isolation layer; and performing an etching process to adjust an effective field height (EFH) of the isolation layer so that the one of the plurality of layers having the smallest etching selectivity ratio remains on a side wall of the conductive layer.

In the above method, the first insulating layer preferably is formed of polysilazane (PSZ) layer formed in a spin-coating manner. The method of this embodiment preferably further comprises performing a heat treatment process after the PSZ layer is formed. In the layers comprising the second insulating layer, the earliest formed layer preferably remains on a side wall of the conductive layer during the etching process.

### BRIEF DESCRIPTION OF THE DRAWINGS

The above and other features and advantages of the invention will become readily apparent with reference to the following detailed description when considered in conjunction with the accompanying drawings wherein:

FIG. 1A to FIG. 1D are sectional views of a flash memory device illustrating a method of forming an isolation layer in a flash memory device according to one embodiment of the invention; and,

FIG. 2A to FIG. 2C are sectional views of a flash memory device illustrating a method of forming an isolation layer in a flash memory device according to another embodiment of the invention.

### DESCRIPTION OF SPECIFIC EMBODIMENTS

Hereinafter, embodiments of the invention will be explained in more detail with reference to the accompanying drawings.

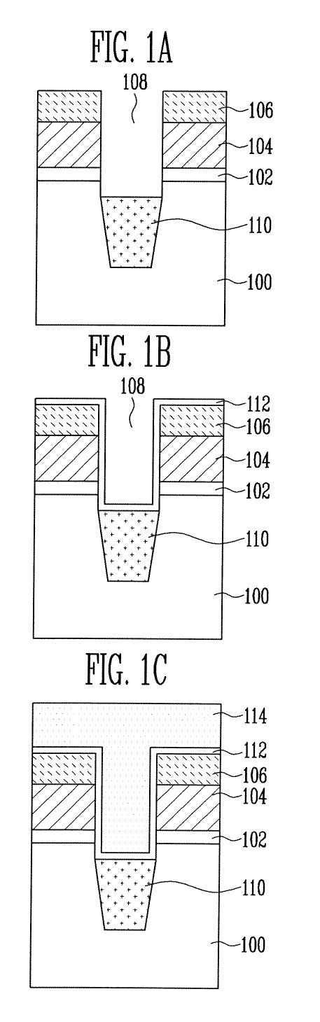

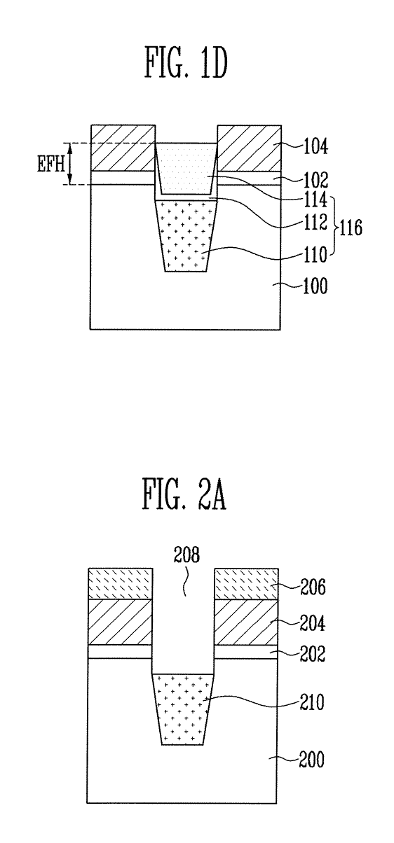

FIG. 1A to FIG. 1D are sectional views of a flash memory device illustrating a method of forming an isolation layer in a flash memory device according to one embodiment of the invention. The processes described below regarding this embodiment relate to a cell region. However, the processes according to this embodiment may be performed on other regions of a device, for example a periphery region.

Referring to FIG. 1A, a tunnel insulating layer 102, a conductive layer 104 for a floating gate and an isolation mask layer 106 are formed on a semiconductor substrate 100. Preferably, the tunnel insulating layer 102 is formed from oxide, the conductive layer 104 is formed from a polysilicon layer, and the isolation mask layer 106 is formed from nitride.

Then, the isolation mask layer 106 is patterned through an etching process. The conductive layer 104, the tunnel insulating layer 102 and a portion of the semiconductor substrate 100 are etched through an etching process in which the patterned isolation mask layer 106 is used as an etching mask to form a trench 108.

Subsequently, a first insulating layer 110 is formed on the semiconductor substrate 100 including the trench 108 to fill the trench 108 with the first insulating layer. Preferably, the first insulating layer 110 is formed from a spin-coated polysilazane (PSZ) layer. Since the polysilazane layer contains a great quantity of impurities and moisture, after the process for forming the polysilazane layer, a heat treatment process is preferably performed to remove impurities and moisture contained in the polysilazane layer and to lower an etching rate of the polysilazane layer.

To remove the first insulating layer 110, a chemical mechanical polishing (CMP) process is then carried out until the isolation mask layer 106 is exposed. Subsequently, a wet etching process is performed to make the first insulating layer 110 remain only on a lower portion of the trench 108.

Referring to FIG. 1B, a second insulating layer 112 is formed on the semiconductor substrate 100 including the trench 108. Preferably, the second insulating layer 112 is formed from a material whose etching selectivity ratio differs from that of the material constituting a third insulating layer (for example, a high density plasma (HDP) layer) to be formed in a subsequent process. Preferably, the second insulating layer is formed from nitride. The second insulating layer 112 is formed through a low pressure-chemical vapor deposition (LP-CVD) method and has a thickness sufficient to prevent a gap-filling process for the trench 108 from being influenced (for example, a thickness by which an increase in the aspect ratio of the trench 108 can be minimized). In a subsequent process for forming the third insulating layer (e.g., the high density plasma oxide layer), a side wall of the conductive layer 104 is damaged by plasma so that a flat side wall of the conductive layer 104 becomes coarse. As a result, numerous protrusions are formed on a side wall of the conductive layer 104. An object of forming the second insulating layer 112 on the semiconductor substrate 100 including the first insulating layer 110 is to prevent the above protrusions from being formed on the side wall of the conductive layer 104. Accordingly, the second insulating layer 112 serves as a protective layer for the conductive layer 104.

Referring to FIG. 1C, a third insulating layer 114 is formed on the semiconductor substrate 100 including the trench 108. Preferably, the third insulating layer 114 is formed from the high density plasma oxide layer. During the process for forming the third insulating layer 114, an overhang can be formed on an edge region of an upper portion of the trench 108. Since the second insulating layer 112 is formed on a side wall of the conductive layer 104, the side wall of the conductive layer 104 is not damaged during the process for forming the third insulating layer 114. On the other hand, a portion of the second insulating layer 112 may be damaged by the plasma.

Subsequently, an etching process is carried out to remove the overhang formed on an edge region of an upper portion of the trench 108. Then, a process for forming the third insulating layer 114 and the etching process for removing the overhang are repeatedly performed.

Referring to FIG. 1D, in order to form an isolation layer 116, a chemical-mechanical polishing (CMP) process is carried out until the isolation mask layer 106 is exposed, and a wet etching process is then performed to adjust the effective field height (EFH) of the isolation layer 116 that includes the first, second, and third insulating layers 110, 112, and 114. Preferably, a wet etching solution having the same etching selectivity ratio between the high density plasma oxide layer and the nitride is used in the wet etching process. In the etching process for adjusting the effective field height (EFH) of the isolation layer 116, the second insulating layer 112 formed on a side wall of the conductive layer 104 is entirely removed. The isolation mask layer 106 also is removed.

Subsequently, a process for forming a dielectric layer and a process for forming a conductive layer for a control gate are performed in conventional manners.

As described above, by forming the second insulating layer 112 formed from nitride on a side wall of the conductive layer 104 before performing the process for forming the high density plasma (HDP) oxide layer, it is possible to prevent a side wall of the conductive layer 104 from being damaged by the plasma during the process for forming the high density plasma (HDP) oxide layer. As a result, numerous protrusions which would otherwise result at a coarse surface of the side wall are not formed on a flat side wall of the conductive layer 104. Due to the above, it is possible to prevent a profile of the conductive layer 104 from being transformed.

In addition, a reduction of a contact surface between the conductive layer and a dielectric layer caused by a transformation of the profile of the conductive layer 104 can be prevented so that a decrease of the coupling ratio (CR) and a decrease in cell operation speed resulting from a decrease of the coupling ratio are prevented.

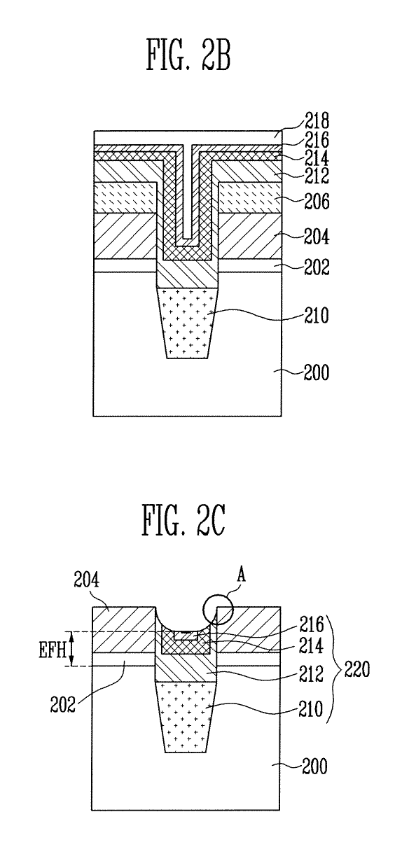

FIG. 2A to FIG. 2C are sectional views of a flash memory device illustrating a method of forming an isolation layer in a flash memory device according to another embodiment of the invention. The processes described below regarding this embodiment relate to a cell region. However, the processes according to this embodiment may be performed on other regions of a device, for example a periphery region.

Referring to FIG. 2A, a tunnel insulating layer 202, a conductive layer 204 for a floating gate and an isolation mask layer 206 are formed on a semiconductor substrate 200. Preferably, the tunnel insulating layer 202 is formed from oxide, the conductive layer 204 is formed from a polysilicon layer, and the isolation mask layer 206 is formed from nitride.

Then, the isolation mask layer 206 is patterned through an etching process. The conductive layer 204, the tunnel insulating layer 202 and a portion of the semiconductor substrate 200 are etched through an etching process, in which the patterned isolation mask layer 206 is used as an etching mask to form a trench 208.

Subsequently, a first insulating layer 210 is formed on the semiconductor substrate 200 including the trench 208 to fill the trench 208 with the first insulating layer. Preferably, the first insulating layer 210 is formed from a spin-coated polysilazane (PSZ) layer. Since the polysilazane layer contains a great quantity of impurities and moisture, a heat treatment process is preferably performed after the process for forming the polysilazane layer to remove impurities and moisture and to lower an etch rate of the polysilazane layer.

To remove the first insulating layer 210, a chemical mechanical polishing (CMP) process is then carried out until the isolation mask layer 206 is exposed. Subsequently, a wet etching process is performed to make the first insulating layer 210 remain only on a lower portion of the trench 208.

Referring to FIG. 2B, a second insulating layer 212, a third insulating layer 214, a fourth insulating layer 216 and a fifth insulating layer 218 are formed on the semiconductor substrate 200 including the trench 208 to fill the trench 208. Preferably, the second insulating layer 212, the third insulating layer 214, the fourth insulating layer 216, and the fifth insulating layer 218 are formed in order of increasing etching selectivity ratio. That is, the second insulating layer 212 is formed from insulative material having an etching selectivity ratio smaller than that of insulative material constituting the third insulating layer 214, the third insulating layer 214 is formed from insulative material having an etching selectivity ratio smaller than that of insulative material constituting the fourth insulating layer 216, and the fourth insulating layer 216 is formed from insulative material having an etching selectivity ratio smaller than that of insulative material constituting the fifth insulating layer 218. The insulating layer formed in the trench 208 does not consist of the second insulating layer 212 to the fifth layer 208, but is formed until the trench is filled therewith. As one example, the structure in which the second insulating layer 212 to the fifth layer 218 are formed is illustrated.

Referring to FIG. 2C, in order to form an isolation layer 220, a chemical-mechanical polishing process is carried out until the isolation mask layer 206 is exposed.

Subsequently, the isolation mask layer 206 is removed, and a wet etching process is then performed to adjust the effective field height (EFH) of the isolation layer 220 that includes the first, second, third, and fourth insulating layers 210, 212, 214, and 216. Preferably, since an etching selectivity ratio of the fifth insulating layer 218 is higher than those of the other insulating layers, the fifth layer 218 is etched more rapidly than the other insulating layers. In addition, since the second insulating layer 212 has the smallest etching selectivity ratio, the second layer 212 formed on a side wall of the conductive layer 204 is not etched while the third insulating layer 214 is etched, and the second layer 212 partially remains on a side wall of the conductive layer 204. Due to the above phenomenon, an upper portion of the isolation layer 220 is rounded downward so that the effective field height (EFH) of the isolation layer 220 becomes lower than that of a corresponding isolation layer formed by a conventional method.

As described above, after the plurality of insulating layers 212, 214, 216, and 218, formed sequentially in order of increasing etching selectivity ratio is formed in the trench 218, some (“A” in FIG. 2C) of the insulating layer remains on a side wall of the conductive layer 204 during the etching process performed for adjusting the effective field height (EFH) of the isolation layer 220 so that it is possible to lower the effective field height (EFH) of the isolation layer 220 to a desired value. Due to the above structure, an interference phenomenon generated between the cells can be reduced.

The effects to be achieved by the invention as described above are as follows.

First, by forming the nitride layer on a side wall of the conductive layer before performing the process for forming the high density plasma (HDP) oxide layer, it is possible to prevent a side wall of the conductive layer from being damaged by the plasma during the process for forming the high density plasma (HDP) oxide layer. As a result, numerous protrusions which would otherwise result at a coarse surface of the side wall are not formed on a flat side wall of the conductive layer.

Second, a transformation of a profile of the conductive layer can be inhibited by preventing a side wall of the conductive layer from being damaged.

Third, a reduction of a contact surface between the conductive layer and a dielectric layer caused by a transformation of the profile of the conductive layer can be prevented so that a decrease of the coupling ratio (CR) and a decrease in cell operation speed resulting from a decrease of the coupling ratio can be prevented.

Fourth, after the insulating layer consisting of a plurality of insulating layers, formed sequentially in order of increasing etching selectivity ratio, is formed in the trench, some of the insulating layer remains on a side wall of the conductive layer during the etching process performed for adjusting the effective field height of the isolation layer so that it is possible to lower the effective field height of the isolation layer to a desired value.

Fifth, the effective field height (EFH) of the isolation layer is lowered to the desired value, and so it is possible to reduce an interference phenomenon generated between the cells.

Although the invention has been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings, and the appended claims. In addition to variations and modifications in the component parts and/or arrangements, alternative uses will also be apparent to those skilled in the art.

What is claimed is:

1. A method of forming an isolation layer in a flash memory device, comprising:
providing a semiconductor substrate comprising a tunnel insulating layer and a conductive layer formed on an active region of the substrate and a trench formed on an isolation region of the substrate;
forming a first insulating layer in a lower portion of the trench;
forming a second insulating layer on the semiconductor substrate and the first insulating layer including the trench to protect a side wall of the conductive layer;
forming a third insulating layer in the trench to form an isolation layer; and
performing a first etching process to adjust an effective field height (EFH) of the isolation layer.

2. The method of forming an isolation layer in a flash memory device of claim 1, wherein forming the first insulating layer comprises spin-coating a polysilazane (PSZ) layer.

3. The method of forming an isolation layer in a flash memory device of claim 2, further comprising performing a heat treatment process after spin-coating the PSZ layer.

4. The method of forming an isolation layer in a flash memory device of claim 1, wherein the second insulating layer has an etching selectivity ratio different from that of the third insulating layer.

5. The method of forming an isolation layer in a flash memory device of claim 1, comprising forming the second insulating layer from nitride.

6. The method of forming an isolation layer in a flash memory device of claim 1, wherein forming the second insulating layer comprises performing a low pressure-chemical vapor deposition (LP-CVD).

7. The method of forming an isolation layer in a flash memory device of claim 1, wherein the third insulating layer comprises a high density plasma (HDP) oxide layer.

8. The method of forming an isolation layer in a flash memory device of claim 1, wherein forming the third insulating layer further comprises performing a second etching process to remove an overhang formed on an edge portion of an upper portion of the trench.

9. The method of forming an isolation layer in a flash memory device of claim 8, wherein the second etching process comprises performing a wet etching process.

10. The method of forming an isolation layer in a flash memory device of claim 1, further comprising removing the second insulating layer formed on a side wall of the conductive layer in the first etching process.

11. A method of forming an isolation layer in a flash memory device, comprising:
providing a semiconductor substrate comprising a tunnel insulating layer and a conductive layer formed on an active region of the substrate and a trench formed on an isolation region of the substrate;
forming a first insulating layer on a bottom surface of the trench;
forming a second insulating layer on the semiconductor substrate and the first insulating layer including the trench, the second insulating layer comprising a plurality of layers formed in order of increasing etching selectivity ratio;
planarizing the second insulating layer to form an isolation layer; and,
performing an etching process to adjust an effective field height (EFH) of the isolation layer so that the one of the plurality of layers having the smallest etching selectivity ratio remains on a side wall of the conductive layer.

12. The method of forming an isolation layer in a flash memory device of claim 11, wherein forming the first insulating layer comprises spin-coating a polysilazane (PSZ) layer formed in a spin coating manner.

13. The method of forming an isolation layer in a flash memory device of claim 12, further comprising performing a heat treatment process after spin-coating the PSZ layer.

14. The method of forming an isolation layer in a flash memory device of claim 11, wherein the earliest formed layer of the plurality of layers remains on a side wall of the conductive layer during the etching process.
